(19) United States
(12) Patent Application Publication
(10) Pub. No.: US 2026/0244165 A1
(43) Pub. Date: Aug. 20, 2026

(54) COMPUTER-IMPLEMENTED METHOD, CONTROL UNIT, COMPUTER PROGRAM, AND COMPUTER-READABLE NON-VOLATILE STORAGE MEDIUM

(71) Applicant: Rohde & Schwarz GmbH & Co. KG, München (DE)

(72) Inventors: Sebastian ROEGLINGER, Pfaffenhofen (DE); Thomas BRAUNSTORFINGER, München (DE); Konstantin BICK, München (DE); Alexander NAEHRING, Ebersberg (DE); Volker OHLEN, Pliening (DE); Michael FEIL, Rot am See (DE); Florian LANG, Gilching (DE)

(21) Appl. No.: 19/373,550

(22) Filed: Oct. 29, 2025

(30) Foreign Application Priority Data
Feb. 20, 2025 (DE) 102025106582.9

(51) Int. Cl. G05B 13/02

(52) U.S. Cl. CPC G05B 13/024

(57) ABSTRACT

The present disclosure relates to a computer-implemented method for controlling at least one measurement application device configured to acquire electrical signals, or generate electrical signals, or acquire and generate electrical signals, the method comprising: acquiring at least one control command for the at least one measurement application device from a user; automatically determining at least one further control command for the at least one measurement application device based on the at least one acquired control command; and controlling the at least one measurement application device based on the acquired and generated control commands. Furthermore, the present disclosure relates to a corresponding control unit, a corresponding computer program, and a corresponding computer-readable non-volatile storage medium.

### TECHNICAL FIELD

The present disclosure relates to a computer-implemented method, a control unit, a computer program, and a computer-readable non-volatile storage medium.

### BACKGROUND

The present disclosure is described below primarily in connection with programming measurement application devices using SCPI (“Standard Commands for Programmable Instruments”), but is not limited thereto.

Typically, measurement application devices are used by application engineers to handle corresponding measurement tasks and, for example, to acquire electrical signals in electrical circuits.

For complex measurement tasks, the measurement application devices can be configured and controlled using corresponding scripts, in particular SCPI scripts.

However, developing such scripts can be very complex and requires corresponding experience on the part of the respective application engineer.

### SUMMARY

An object of the present disclosure is therefore to support users of a measurement application device in configuring and operating it.

The object is solved by the subject matter of the independent claims.

Disclosed is:
A computer-implemented method for controlling at least one measurement application device, which is configured to acquire electrical signals, or to generate electrical signals, or to acquire and generate electrical signals, wherein the method comprises: acquiring at least one control command for the at least one measurement application device from a user, automatically determining at least one further control command for the at least one measurement application device based on the at least one acquired control command, and controlling the at least one measurement application device based on the acquired and the generated control commands.

Further disclosed is:
A control unit for controlling at least one measurement application device, wherein the control unit comprises means for executing a method according to the present disclosure.

Further disclosed is:
A computer program comprising instructions which, when executed by a computer, cause the computer to execute a method according to the present disclosure.

Further disclosed is:
A computer-readable non-volatile storage medium comprising instructions which, when executed by a computer, cause the computer to execute a method according to the present disclosure.

The present disclosure is based on the insight that with modern measurement application devices, a very large number of possible configuration options and operating options exist. Due to this large number, it can be difficult for users to know all configuration options and operating options.

If a user employs a scripting language, such as SCPI, the quality of a corresponding script depends not only on the user's knowledge of the configuration options and operating options or commands. Rather, the quality of such a script also depends on the user's experience in programming such scripts. Scripts that fulfill the same measurement task can therefore exhibit different qualities-depending on which user developed them. Different scripts can therefore exhibit, for example, different runtimes or achieve different results or results with different accuracies.

The present disclosure takes this insight into account and provides a computer-implemented method and a control unit which are configured to support a user in developing scripts for controlling measurement application devices.

The subject matter of the present disclosure supports a user in developing such scripts by automatically determining control commands for the at least one measurement application device based on control commands already specified or entered by a user.

The specified control commands can, for example, be entered by a user or read from a script already created by a user.

The further control commands can be determined or generated, for example, based on corresponding statistical or mathematical methods. Artificial intelligence algorithms are also possible.

The further control commands can particularly relate to or include or implement typically occurring sequences of control commands.

During the automatic determination of the further control commands, different suggestions can be presented to the user, from which he can select the desired suggestion. The suggestions may merely identify the respective measurement task, while the specific control commands can be generated after a selection by the user. For example, the user can be suggested the most frequently performed measurement tasks based on the already known or acquired control commands, or the measurement tasks can be displayed in the order of their frequency. A manufacturer of measurement application devices can determine and store or provide the frequency, for example, based on statistical evaluations. The number of displayed suggestions can be limited in embodiments, for example to three. If the user rejects all displayed suggestions, the next suggestions can be displayed to the user.

If the user specifies or selects a corresponding measurement task, corresponding suggestions for settings that are typically made for the respective measurement task can be displayed to the user.

For example, the user can specify that he wants to perform an EMC measurement for a 5G communication device. Corresponding suggestions can be presented to the user, such as “A) Clamp calibration cable”, “B) Measure at reference level −10 dBmC”, “C) Set a ResBW of 10 kHz”.

The further control commands can be used to supplement the existing control commands or to replace them after they are determined. In embodiments, the user can, for example, mark or select control commands in a given sequence or script that are to be optimized or replaced. Using the present disclosure, existing scripts can thus be optimized at least in parts, but also completely replaced.

Within the scope of this disclosure, the term “control command” is to be understood as any possible command that can be transmitted to a measurement application device to set a parameter in the measurement application device or to trigger an action in the measurement application device. Corresponding control commands can be configured, for example, as SCPI commands.

The control commands can also be configured as inputs, at least simulated inputs, at a user interface of the respective measurement application device. When controlling the at least one measurement application device, the control commands can be displayed as corresponding inputs on the user interface of the respective measurement application device. Manual step-by-step execution of the control commands by the user is possible. For this purpose, it can be provided, for example, that a user accepts each of the displayed control commands in the user interface before it is executed. Generally, an approval of the generated control commands by the user can be provided for, regardless of the type of control commands. For this purpose, they can be displayed to the user and only used to control the at least one measurement application device after approval by the user.

In embodiments, the control commands provided by the user can be configured, for example, as inputs at a user interface of one of the measurement application devices. To generate the further control commands, these inputs can be translated into corresponding control commands of a programming or scripting language, and the further control commands can be generated in this programming or scripting language.

In addition to the aforementioned SCPI-based control commands, the control commands can also be provided in other scripting or programming languages. Such scripting or programming languages can include, for example, Python, C, C++, Basic, or Assembler, but are not limited to these examples.

It is understood that the control commands can be generated for a single measurement application device or for several measurement application devices that are used to jointly solve a measurement task.

A measurement application device according to the present disclosure can include any device that is used in a measurement application to acquire an input signal or to generate an output signal, or performs additional or supporting functions in a measurement application. A measurement application device can also be implemented as a program or software application that runs as a measurement application on a computer or processor and can communicate with other measurement application devices to fulfill a measurement task. A measurement application, also referred to as a measurement or test setup, can include, for example, at least one or several different measurement application devices used for electrical, magnetic, or electromagnetic measurements, particularly on individual devices under test, also called DUT. A measurement application device according to the present disclosure can be configured to perform such electrical, magnetic, or electromagnetic measurements or signal generations, for example in a measurement laboratory or in a production facility in the respective production line on a device under test. An exemplary measurement setup can serve to qualify the individual devices under test, i.e., to verify the proper electrical function of the respective devices under test.

For this purpose, measurement application devices can include at least one signal acquisition part for acquiring electrical, magnetic, or electromagnetic signals from the device under test and/or at least one signal generation part for generating electrical, magnetic, or electromagnetic signals that can be supplied to the device under test. Such a signal acquisition part can include, for example but not limited to, a front-end stage for acquiring, filtering, attenuating, or amplifying electrical signals. The signal generation part can include, for example but not limited to, corresponding signal generators, amplifiers, and filters. In embodiments, signal acquisition via the signal acquisition part is performed in a wired or contact-based manner. For this purpose, a corresponding measurement probe (also called probe) can be connected to the measurement application device via a corresponding cable. Similarly, in embodiments, signal generation and output via the signal generation part are performed in a wired or contact-based manner. For this purpose, a corresponding signal output probe can be connected to the measurement application device via a corresponding cable, or the signal is output directly via the cable, e.g., to a device under test. In further embodiments, signal acquisition can be contactless, e.g., via corresponding antennas, also called OTA or over-the-air. In further embodiments, signal generation and output can be contactless, e.g., via corresponding antennas, also called OTA or over-the-air. A combination of contact-based signal acquisition, contactless signal acquisition, contact-based signal generation and output, and contactless signal generation and output is also possible.

Furthermore, measurement application devices can include a signal processing unit for processing the acquired signals during signal acquisition. The processing can include converting the acquired signals from analog to digital signals or vice versa and any other type of digital signal processing, for example converting time-domain signals to frequency-domain signals.

The measurement application devices can also have a user interface to display the acquired signals to the user and to enable the user to control the measurement application devices. Of course, a housing can be provided that encloses the elements of the measurement application device. It is understood that additional elements such as a power supply circuit and communication interfaces can be provided.

A measurement application device can be a standalone device that can be operated in a measurement application without further elements to perform tests on a device under test. Naturally, communication capabilities can also be provided to connect the measurement application device to other measurement application devices.

A measurement application device can be, for example, a signal recording device such as an oscilloscope, particularly a digital oscilloscope, a spectrum analyzer, or a vector network analyzer. A measurement application device can also include a signal generation device, e.g., a signal generator, particularly a so-called “Arbitrary Signal Generator”, also referred to as an “Arbitrary Waveform Generator”, or a vector signal generator. Further possible measurement application devices include devices such as calibration standards or measurement probe tips.

Of course, at least some of the possible functions, such as signal recording and signal generation, can be combined in a single measurement application device.

In embodiments, the measurement application device can include pure data acquisition devices that are capable of acquiring an input signal and transmitting the acquired input signal as a digital input signal to a corresponding data storage or application server. Such pure data acquisition devices do not necessarily have a user interface or display. Instead, such pure data acquisition devices can be remotely controlled, e.g., via a corresponding data connection such as a network interface or a USB interface. The same applies to pure signal generation devices that can generate an output signal without having a user interface or configuration input devices. Instead, such signal generation devices can be operated remotely via a data connection.

The control unit according to the present disclosure can comprise a commercial computer. Such a computer can be coupled to the at least one measurement application device via a corresponding interface, e.g., a USB or network interface. Furthermore, such a computer can have a user interface that allows a user to interact with the computer. Such a user interface can include, for example, a screen, a mouse and a keyboard, or a touchscreen. The control unit can execute the computer program according to the present disclosure. For this purpose, the computer program can, for example, be loaded and executed by an operating system running on the control unit.

The control unit according to the present disclosure can also be configured as a server, which can be coupled to the at least one measurement application device via a corresponding interface. This interface can be, for example, a network interface. In embodiments, the control unit can deliver a user interface as a web page, which can be accessed and displayed via corresponding browser software.

In further embodiments, the control unit can be arranged in a measurement application device or implemented by the measurement application device. In such embodiments, the control unit can be arranged as a standalone unit in the measurement application device. The control unit can also be implemented by the elements already present in the measurement application device. For example, a processor of the measurement application device can execute a computer program according to the present disclosure.

The present disclosure enables users to efficiently create sequences or scripts of control commands for measurement application devices and thereby efficiently solve measurement tasks.

Further embodiments and developments result from the dependent claims as well as from the description with reference to the figures. In particular, all embodiments mentioned herein can be combined with each other in any order or number, unless individual features are mutually exclusive. In particular, the dependent claims of one claim category can also be developed according to another claim category.

In an embodiment combinable with all embodiments mentioned herein, the automatic determination of further control commands can comprise determining control commands that exhibit optimization with respect to at least one predefined goal. Exemplary goals can be to maximize an execution speed of a sequence of control commands, to maximize an accuracy of the at least one measurement application device, and to optimize a load on the at least one measurement application device.

When generating the further control commands, a user can specify corresponding priorities.

For example, the execution of corresponding scripts in a measurement application device can have a high runtime if a certain measurement accuracy must be achieved or if certain analysis of the acquired measurement data are necessary.

However, if a user only requires low measurement accuracy or no further data analysis, the user can specify that the execution speed of the generated sequence of control commands should be maximized. In such embodiments, for example, the measurement accuracy can be reduced or further analysis of the acquired measurement data can be omitted.

If, on the other hand, the highest possible measurement accuracy is important for a measurement task, the user can specify that the measurement accuracy should be maximized by the generated sequence of control commands. An increased runtime may be accepted in this case.

Modern measurement application devices, such as signal generators, can comprise components that age quickly under high load. Such components can be, for example, amplifiers. One of the goals in generating the further control commands can therefore be, for example, to limit or reduce the load on such components to optimize the service life of the respective measurement application device.

In embodiments, multiple goals can also be specified. These can be treated equally or prioritized among themselves.

In yet another embodiment combinable with all embodiments mentioned herein, the automatic determination of further control commands can comprise at least one of the following options: determining a single control command, determining a sequence with a predefined number of control commands, and determining a sequence of control commands that completely handles a measurement task.

When generating the further control commands, different operating modes can be selected by the user. The user can, for example, specify that a single control command should be generated each time. Only after approval of the control command by the user is a further control command generated, or if rejected by the user, the generated control command is discarded and regenerated.

In a further embodiment, a sequence with a predetermined number of control commands can be generated. Only after approval of the sequence by the user can a further sequence be generated, or if rejected by the user, the generated sequence is discarded and regenerated. This enables a user to, for example, check and approve the script for a corresponding measurement task in manageable sections.

In yet another embodiment, a sequence of control commands for an entire measurement task can be generated, so that the sequence completely fulfills the measurement task. Before controlling a measurement application device, the sequence can be displayed to a user for approval.

In further embodiments, the further control commands may not be displayed to the user for approval before controlling the at least one measurement application device.

In a further embodiment combinable with all embodiments mentioned herein, the determined further control commands can comprise at least one of the following options: control commands of a scripting language for controlling the at least one measurement application device, configuration commands for configuring operating parameters of the at least one measurement application device, configuration parameters for setting the operating parameters of the at least one measurement application device, configuration commands for configuring a hardware of the at least one measurement application device, and configuration parameters for configuring the hardware of the at least one measurement application device.

The individual control commands generated according to the present disclosure can fulfill different tasks. The control commands can comprise, for example, commands of a scripting language that control the at least one measurement application device.

Control commands within the scope of the present disclosure can particularly be configuration commands or corresponding configuration parameters that serve to configure the at least one measurement application device.

A distinction can be made regarding the level at which the configuration commands and configuration parameters operate.

When executing, for example, SCPI scripts, a parser analyzes the respective script command by command. From this analysis of individual commands, corresponding parameter values are calculated and a configuration, e.g., in the form of register values, is derived for a logic layer of the respective measurement application device. Subsequently, the hardware of the respective measurement application device is configured accordingly. The parser in particular is computationally intensive. For complex scripts, long runtimes can therefore occur.

If the control commands are generated such that they directly comprise configuration commands for configuring operating parameters and/or the configuration parameters for setting the operating parameters, the time-consuming execution of the parser can consequently be skipped or bypassed. The term “operating parameters” refers to the parameters of the measurement application device that relate to the firmware or software of the measurement application device.

In contrast, configuration commands for configuring a hardware and/or the configuration parameters for configuring the hardware can also be generated as control commands. Such configuration commands or configuration parameters relate directly to the hardware or the settings or configurations of the hardware of the respective measurement application device.

By correspondingly predicting or anticipating the configuration commands and configuration parameters, the execution of the respective script can consequently be significantly accelerated since the parser can be skipped.

In an embodiment combinable with all further embodiments, after parsing a first control command, one or more further control commands can be automatically determined that can follow the parsed control command while the parsed control command is still being processed.

Typically, an SCPI script, as described above, is transmitted to a measurement application device command by command or processed by the measurement application device. In such measurement application devices, a control command is completely processed, i.e., the hardware is also configured accordingly, before the next command is processed.

Using the method according to the present disclosure, one or more possible further control commands can already be determined in parallel to the processing of the first parsed control command. For these further control commands, parameter values can then already be calculated in parallel and a configuration, e.g., in the form of register values, derived for a logic layer of the respective measurement application device.

In the event that one of the control commands is the correct control command that follows the parsed control command in the SCPI script, the hardware can thus be set directly. The execution of the SCPI scripts is thus significantly accelerated.

In an embodiment combinable with all further embodiments, for each of the further control commands, multiple variants can be generated in parallel, particularly also for sequences of control commands. The different variants can subsequently be verified. For this, a simulation can be used, for example. Subsequently, the most successful variant, i.e., for example, the one with the best simulation results regarding the predefined goal, can be selected. Alternatively, the different variants can be displayed to the user for selection.

Furthermore, alternative control commands or sets of control commands can be generated for the case that a user rejects a suggested control command.

Corresponding sets of configuration commands and/or configuration parameters can be generated, which can be kept available in parallel. This also applies to individual subsections of a sequence of control commands. The control commands can consequently be treated similarly to branch prediction and branching in a modern processor. If a user selects a specific variant, for example, the corresponding configuration commands and/or configuration parameters can be executed directly, and the other variants can be discarded. In embodiments, the other variants can also be stored so that the user can undo a control command or a sequence of control commands and select a different control command or a different control sequence.

The hardware of the measurement application devices can comprise, for example, corresponding shadow registers or shadow register banks in which different parameters can be stored.

In yet another embodiment combinable with all embodiments mentioned herein, the method can further comprise outputting the determined at least one further control command to a user, and receiving an approval or rejection of the determined at least one further control command from the user, wherein the controlling of the at least one measurement application device is executed upon receiving an approval of the determined at least one further control command from the user and is not executed upon a rejection.

The respective measurement application devices can be controlled directly based on the generated control commands without querying further inputs or approvals from a user. However, this could lead to unintended or faulty control commands.

It can therefore be provided to display the generated further control commands to the user before they are transmitted to the measurement application devices or executed by them.

In an embodiment combinable with all embodiments mentioned herein, the automatic determination of further control commands can comprise transferring the at least one acquired control command to a trained AI algorithm, wherein the trained AI algorithm is trained to determine and output the further control commands based on the at least one acquired control command.

As mentioned above, different possibilities can be used to determine the further control commands. In addition to the mentioned statistical methods, AI-based algorithms or AI algorithms can be used to determine or generate the further control commands. Corresponding algorithms can be, for example, so-called LLMs or “Large Language Models”. However, the usable algorithms are not limited to these. Other AI-based algorithms or machine learning algorithms can also be used. The respective algorithm can be supplied with the existing control commands with the instruction to generate the further control commands.

The algorithms can be trained accordingly to generate the further control commands. For this, an existing algorithm or an existing model can be refined or trained in an additional training. This enables providing an AI-based algorithm that can consider the specific properties of the measurement application devices without having to train a corresponding model from scratch.

Additionally or alternatively, the AI algorithm can be used in a so-called RAG pipeline. RAG stands in this context for “Retrieval-Augmented Generation”. In such an embodiment, additional information, e.g., the already existing control commands or further technical information about the measurement application devices, can be correspondingly prepared and passed to the AI algorithm together with the instruction to generate new control commands. The preparation of this data can comprise, for example, tokenizing, i.e., splitting into individual tokens, and vectorizing the tokens, which can then be stored in a vector database, also called embedding. To select the relevant tokens from the vector database, the original query, e.g., the already existing control commands and the instruction to generate further control commands, can also be subjected to tokenization and vectorization. Based on a similarity search in the vector database, the relevant entries from the database can subsequently be identified and transmitted to the AI algorithm together with the original query.

In yet another embodiment combinable with all embodiments mentioned herein, the automatic determination of further control commands can further comprise transferring the at least one acquired control command to at least one further trained AI algorithm, wherein the at least one further trained AI algorithm is also trained to determine and output the further control commands based on the at least one acquired control command.

To ensure the quality of the generated control commands, the same query, optionally including the aforementioned additions within the scope of a RAG pipeline, can be passed to at least a second AI algorithm.

Subsequently, the results of the different AI algorithms can be compared. A comparison of the results can comprise directly comparing the individual control commands. However, the comparison can also comprise simulating the control commands, wherein the generated control commands are assumed to be “identical” or “equal” if the simulation results are identical or at least lie within predefined confidence intervals.

If the control commands generated by different AI algorithms are evaluated as “identical” or “equal”, the generated control commands can be marked as correct or error-free.

Such a comparison or the corresponding simulation with comparison of the results can also be used, for example, when existing control commands are to be optimized. In such applications, the existing control commands and the corresponding generated control commands can be simulated and compared.

In yet another embodiment combinable with all embodiments mentioned herein, the method can further comprise: feeding feedback on the determined at least one further control command to the AI algorithm, and generating further control commands based on the feedback, and/or training the AI algorithm based on the feedback.

Feedback on the generated control commands can be used to continuously further develop or train the AI algorithm during its operation.

If the feedback is used for further training, the user can be asked whether he agrees to the storage of the control commands provided by him and his feedback.

The feedback can be queried from a user or automatically generated from the rejection or acceptance of a control command or a sequence of control commands by the user. When querying the feedback, the user can also provide an improvement of the respective control command or the respective sequence of control commands, which can be transmitted to the AI algorithm.

The feedback can also be used to refine or supplement already generated control commands. For this, the user can be given the possibility to enter his feedback on the generated control command in text form. Alternatively, a so-called STT or Speech-To-Text algorithm can be used to convert the user's feedback into text, which can be fed to the AI algorithm as feedback. For the output of the AI algorithm, a TTS or Text-To-Speech algorithm can also be provided.

The AI algorithm can in such embodiments be configured to conduct a dialogue with the user until the user agrees with the generated control commands.

In a further embodiment combinable with all embodiments mentioned herein, the AI algorithm can be trained based on at least one of the following options: pre-prepared sequences of control commands for the at least one measurement application device, descriptions of the pre-prepared sequences, data sheets of the at least one measurement application device, Application Notes for the at least one technical device, sequences generated by the method according to one of the preceding claims, and user feedback on the generated sequences.

As explained above, the AI algorithm can be based on a generally trained AI model. To improve the generated control commands, an AI model can be trained or fine-tuned with the information mentioned here.

This makes it possible to provide the AI algorithm with specific knowledge, e.g., manufacturer-specific knowledge about certain measurement application devices or known scripts or programs for solving certain measurement tasks. The quality of the generated control commands can thus be improved.

In a further embodiment combinable with all embodiments mentioned herein, the method can further comprise: storing a sequence of control commands by means of which the at least one measurement application device is controlled, and receiving an undo input from a user, wherein the undo input relates to a control command of the sequence, and resetting the at least one measurement application device to the state of the control command to which the undo input relates.

When controlling measurement application devices by means of automatically generated control commands, it can occur that a user accepts or executes a command without fully checking it.

To enable a user to set the respective measurement application device or a group of measurement application devices to a state prior to the execution of an incorrect or faulty command, the sequence of control commands executed with the at least one measurement application device can be stored.

A user can thereby jump back at any time to one of the already executed control commands. The “jumping back” can also comprise setting the respective measurement application devices to the corresponding state. Thus, not only is a jump made to the control command in the sequence to execute other control commands from this command. Rather, the respective measurement application devices are also set to the state they had at that time. Changes to the configurations of the respective measurement application devices made by subsequent control commands are thus also undone.

When generating the control commands, they can particularly be selected or weighted according to how much effort is required to undo them. Control commands that cause low effort when undoing can be preferred in this process.

In a further embodiment combinable with all embodiments mentioned herein, the acquiring of the at least one control command can comprise acquiring a user input via an input interface of the at least one measurement application device, wherein the controlling of the at least one measurement application device comprises simulating a user input via the input interface of the at least one measurement application device.

As already explained above, the control commands can be provided not only as script or program code. Rather, the control commands can also be acquired and displayed as user inputs via a user interface, e.g., on a display or touchscreen, of the respective measurement application device. “Simulating” a user input can be understood to mean that the same effect is achieved as if the user had actually made the input. In embodiments, the “simulating” can comprise displaying the user input in or on a user interface of the respective measurement application device. This input can be executed automatically, or user confirmation can be queried.

### BRIEF DESCRIPTION OF THE DRAWINGS

The present disclosure is explained in more detail below based on the exemplary embodiments indicated in the schematic figures of the drawings.

FIG. 1 shows a flowchart of an embodiment of a method according to the present disclosure;

FIG. 2 shows a flowchart of a further embodiment of a method according to the present disclosure;

FIG. 3 shows a flowchart of a further embodiment of a method according to the present disclosure;

FIG. 4 shows a flowchart of a further embodiment of a method according to the present disclosure;

FIG. 5 shows a flowchart of a further embodiment of a method according to the present disclosure;

FIG. 6 shows a flowchart of a further embodiment of a method according to the present disclosure;

FIG. 7 shows a block diagram of a further embodiment of a system according to the present disclosure;

FIG. 8 shows a block diagram of an oscilloscope, which can be an embodiment of a measurement application device according to the present disclosure; and

FIG. 9 shows a block diagram of a further oscilloscope, which can be an embodiment of a measurement application device according to the present disclosure.

In all figures, functionally equivalent elements and devices-unless otherwise specified-have been provided with similar reference signs that are at least identical in the two least significant digits (units and tens).

### DETAILED DESCRIPTION OF THE DRAWINGS

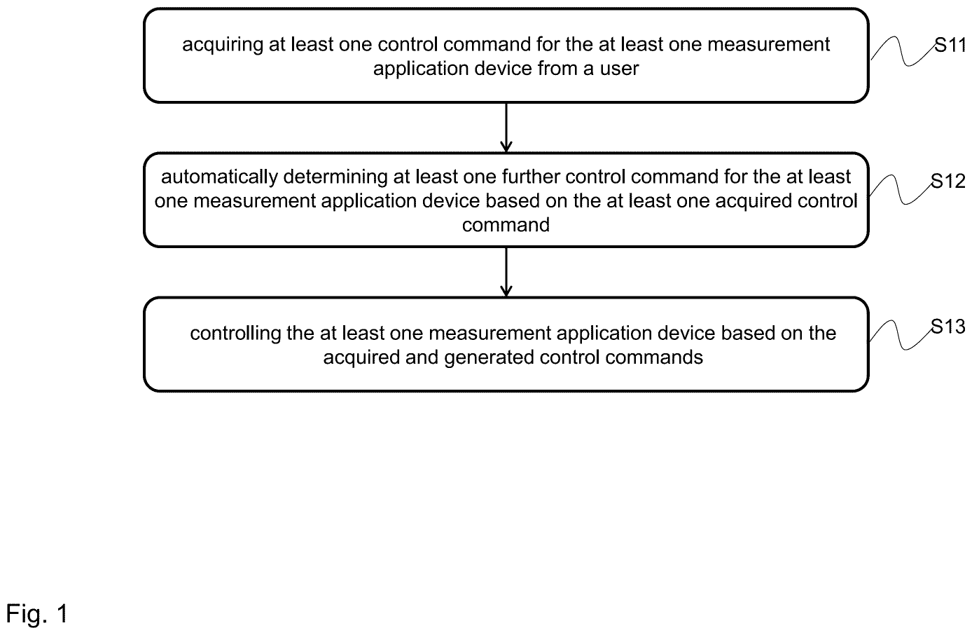

FIG. 1 shows a flowchart of a computer-implemented method for controlling at least one measurement application device 102-1, 102-2, which is configured to acquire electrical signals, or to generate electrical signals, or to acquire and generate electrical signals.

The method comprises acquiring S11 at least one control command 103 for the at least one measurement application device 102-1, 102-2 from a user, automatically determining S12 at least one further control command 103 for the at least one measurement application device 102-1, 102-2 based on the at least one acquired control command 103, and controlling S13 the at least one measurement application device 102-1, 102-2 based on the acquired and the generated control commands 103.

The control commands 103 can be acquired as program code or script code. Alternatively or additionally, the control commands 103 can be acquired as a user input via an input interface of the at least one measurement application device 102-1, 102-2. The controlling of the at least one measurement application device 102-1, 102-2 can comprise simulating a user input via the input interface of the at least one measurement application device 102-1, 102-2.

The automatically determining S12 can comprise determining control commands 103 that exhibit optimization with respect to at least one predefined goal. As optimization goals, for example, the following goals can be predefined: maximizing an execution speed of a sequence of control commands 103, maximizing an accuracy of the at least one measurement application device 102-1, 102-2, and optimizing a load on the at least one measurement application device 102-1, 102-2.

The determined further control commands 103 can comprise at least one of the following options: control commands 103 of a scripting language for controlling the at least one measurement application device 102-1, 102-2, configuration commands for configuring operating parameters of the at least one measurement application device 102-1, 102-2, configuration parameters for setting the operating parameters of the at least one measurement application device 102-1, 102-2, configuration commands for configuring a hardware of the at least one measurement application device 102-1, 102-2, and configuration parameters for configuring the hardware of the at least one measurement application device 102-1, 102-2.

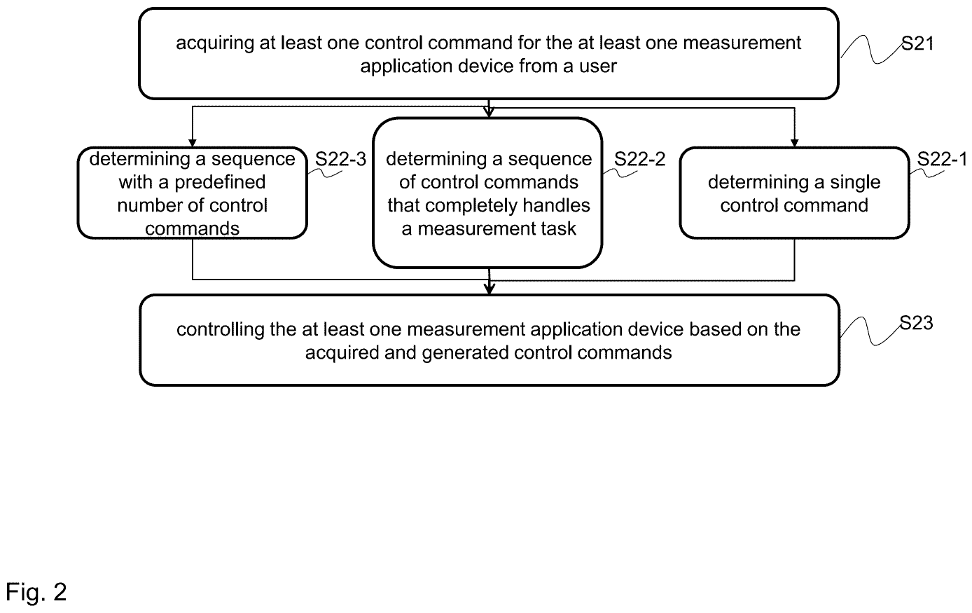

FIG. 2 shows a flowchart of a further method based on the method of FIG. 1. The method of FIG. 2 therefore comprises acquiring S21 at least one control command 103 for the at least one measurement application device 102-1, 102-2 from a user, and controlling S23 the at least one measurement application device 102-1, 102-2 based on the acquired and generated control commands 103.

The automatically determining of further control commands 103 in the method of FIG. 2 comprises at least one of the following options: determining S22-1 a single control command 103, determining S22-2 a sequence with a predefined number of control commands 103, and determining S22-3 a sequence of control commands 103 that completely handles a measurement task.

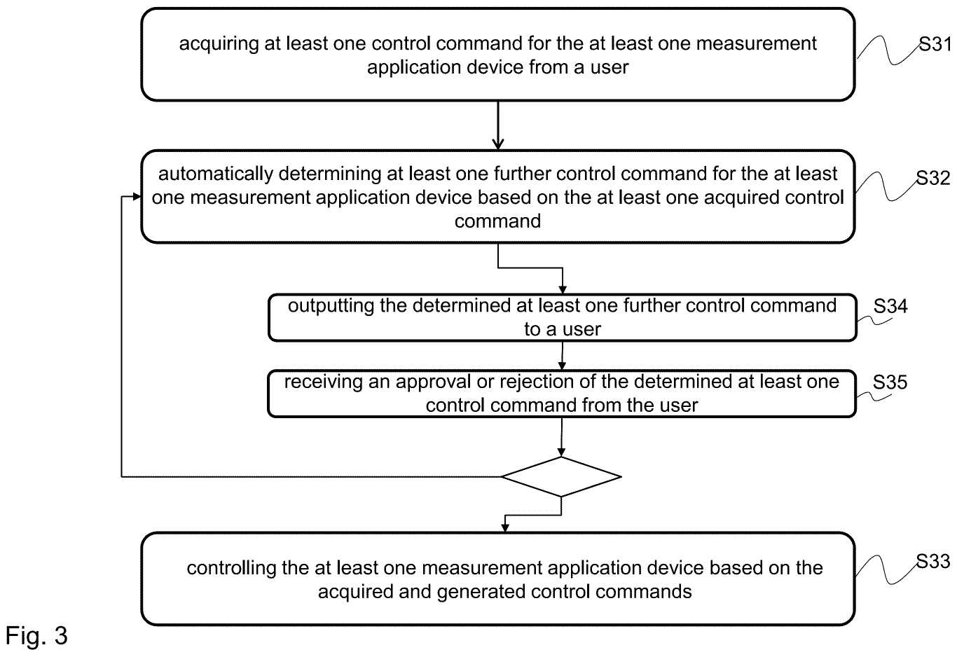

FIG. 3 shows a flowchart of a further method based on the method of FIG. 1. The method of FIG. 3 therefore comprises acquiring S31 at least one control command 103 for the at least one measurement application device 102-1, 102-2 from a user, automatically determining S32 at least one further control command 103 for the at least one measurement application device 102-1, 102-2 based on the at least one acquired control command 103, and controlling S33 the at least one measurement application device 102-1, 102-2 based on the acquired and the generated control commands 103.

Furthermore, the method of FIG. 3 provides, before controlling S33 the at least one measurement application device 102-1, 102-2, outputting S34 the determined further control commands 103 to a user, and receiving S35 an approval or rejection of the determined at least one control command 103 from the user.

The controlling of the at least one measurement application device 102-1, 102-2 is executed upon receiving an approval of the determined at least one control command 103 from the user. Upon rejection, the at least one measurement application device 102-1, 102-2 is not controlled.

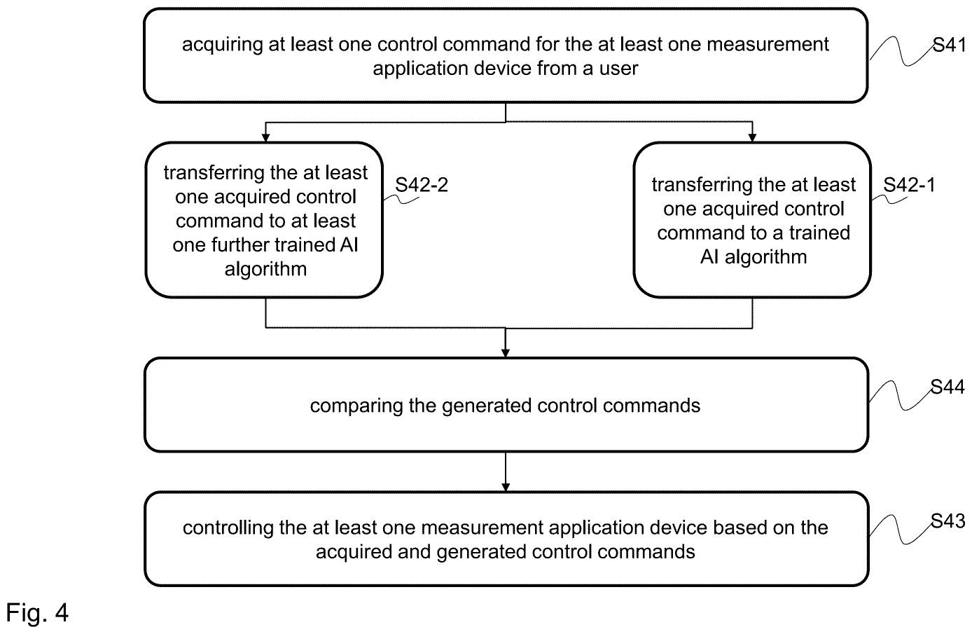

FIG. 4 shows a flowchart of a further method based on the method of FIG. 1. The method of FIG. 4 therefore comprises acquiring S41 at least one control command 103 for the at least one measurement application device 102-1, 102-2 from a user, and controlling S43 the at least one measurement application device 102-1, 102-2 based on the acquired and generated control commands 103.

The automatically determining of further control commands 103 in the method of FIG. 4 comprises transferring S42-1 the at least one acquired control command 103 to a trained AI algorithm, wherein the trained AI algorithm is trained to determine and output the further control commands 103 based on the at least one acquired control command 103.

Optionally, the at least one acquired control command 103 can be transferred S42-2 to at least one further trained AI algorithm, wherein the at least one further trained AI algorithm is also trained to determine and output the further control commands 103 based on the at least one acquired control command 103.

If two trained AI algorithms are used, a further step can be provided in which the results of the two AI algorithms can be reconciled or compared. The controlling of the at least one measurement application device 102-1, 102-2 can then occur based on the corresponding result of the reconciliation.

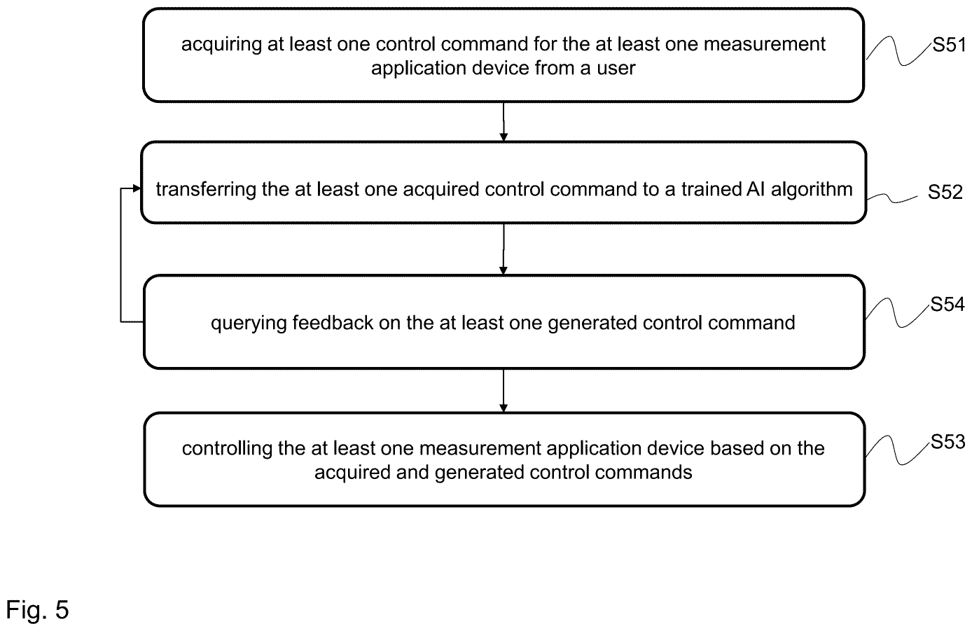

FIG. 5 shows a flowchart of a further method based on the method of FIG. 1. The method of FIG. 5 therefore comprises acquiring S51 at least one control command 103 for the at least one measurement application device 102-1, 102-2 from a user, and controlling S53 the at least one measurement application device 102-1, 102-2 based on the acquired and the generated control commands 103.

The automatically determining of further control commands 103 in the method of FIG. 5 comprises transferring S52 the at least one acquired control command 103 to a trained AI algorithm, wherein the trained AI algorithm is trained to determine and output the further control commands 103 based on the at least one acquired control command 103.

The method of FIG. 5 further provides querying S54 feedback on the at least one generated control command from a user and regenerating the at least one acquired control command 103 if it is negative.

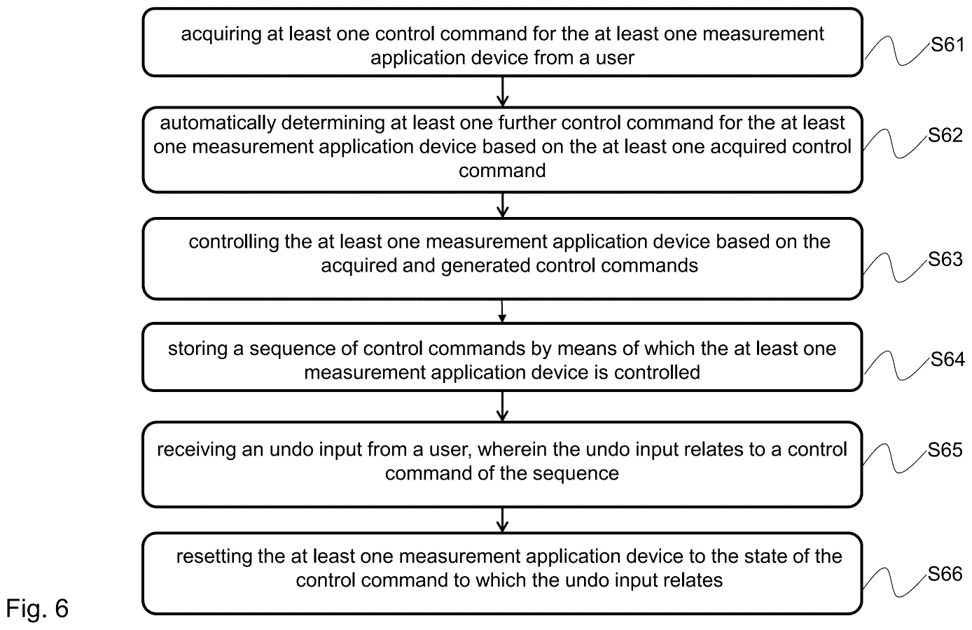

FIG. 6 shows a flowchart of a further method based on the method of FIG. 1. The method of FIG. 6 therefore comprises acquiring S61 at least one control command 103 for the at least one measurement application device 102-1, 102-2 from a user, automatically determining S62 at least one further control command 103 for the at least one measurement application device 102-1, 102-2 based on the at least one acquired control command 103, and controlling S63 the at least one measurement application device 102-1, 102-2 based on the acquired and the generated control commands 103.

Furthermore, the method of FIG. 6 comprises storing S64 a sequence of control commands 103 by means of which the at least one measurement application device 102-1, 102-2 is controlled, and receiving S65 an undo input from a user, wherein the undo input relates to a control command 103 of the sequence, and resetting S66 the at least one measurement application device 102-1, 102-2 to the state of the control command 103 to which the undo input relates.

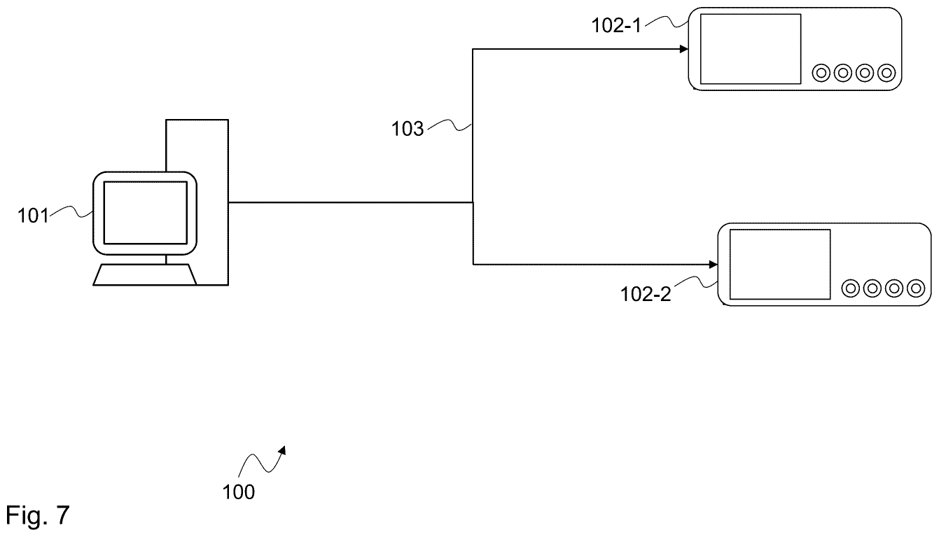

FIG. 7 shows a block diagram of an embodiment of a system 100 with a control unit 101 for controlling measurement application devices, wherein two measurement application devices 102-1, 102-2 are shown by way of example in the system 100.

The control unit 101 is configured as a computer that can be used by a user to generate control commands 103 for the measurement application devices 102-1, 102-2.

In particular, software enabling the development of programs or scripts with control commands 103, also called an IDE, can be installed on the computer. The computer program according to the present disclosure can be integrated into such software. Alternatively, the computer can communicate with a further control unit, e.g., a server, which executes the computer program according to the present disclosure.

It is understood that such a server can comprise corresponding hardware for operating corresponding AI algorithms and can be provided, for example, in a data center or as a cloud service.

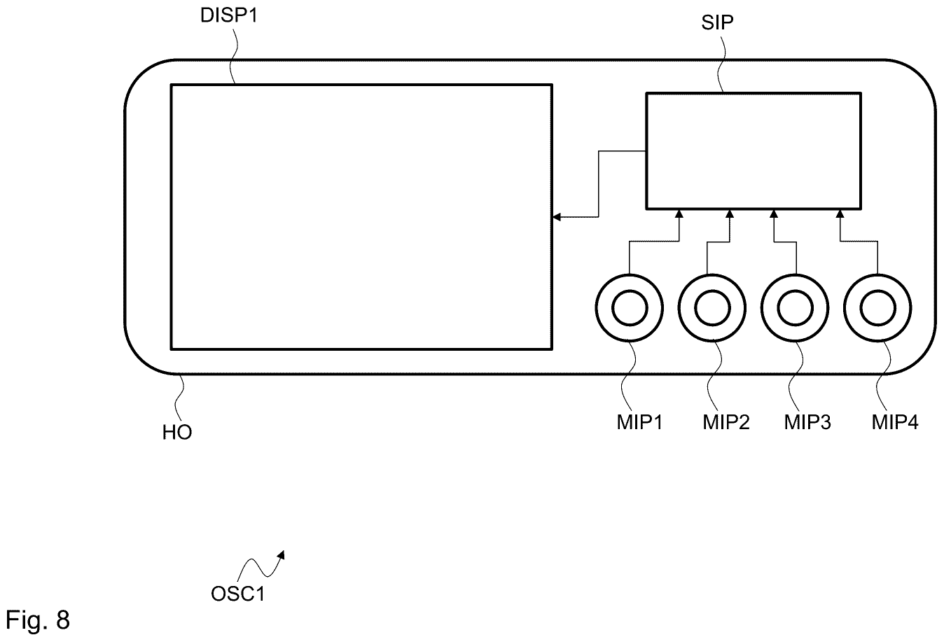

FIG. 8 shows a block diagram of an oscilloscope OSC1, which can be an embodiment of a measurement application device according to the present disclosure or can implement such a device.

The oscilloscope OSC1 comprises a housing HO that accommodates four measurement inputs MIP1, MIP2, MIP3, MIP4, which are connected to a signal processor SIP to process measured signals. The signal processor SIP is connected to a display DISP1 to display the measured signals to a user.

Although not explicitly shown, it is understood that the oscilloscope OSC1 can also comprise signal outputs. Such signal outputs can serve, for example, to output calibration signals. Such calibration signals allow the calibration of the measurement setup before performing measurements. The process of calibrating and correcting measurement signals based on the calibration can also be referred to as “De-Embedding” and can comprise applying corresponding algorithms to the generated or measured signals.

In the oscilloscope OSC1, the signal processor SIP or an additional processing element can perform or implement the function of a control unit according to the present disclosure. Naturally, a communication interface for communication with other measurement application devices can be provided in the oscilloscope OSC1.

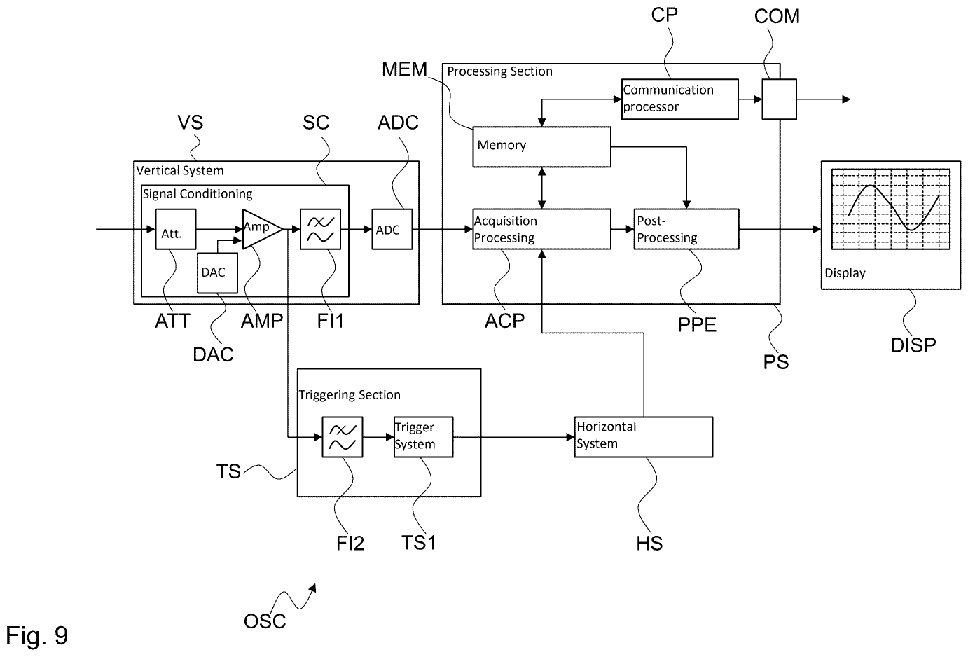

FIG. 9 shows a block diagram of a further oscilloscope OSC, which can be an implementation of a measurement application device according to the present disclosure or can comprise such a device. The oscilloscope OSC is implemented as a digital oscilloscope. However, it is noted that the present disclosure can also be implemented with any other type of oscilloscope.

The oscilloscope OSC comprises five general sections by way of example: the vertical system VS, the triggering section TS, the horizontal system HS, the processing section PS, and the display DISP. It is understood that the division into five general sections represents a logical division and in no way restricts the placement and implementation of the elements of the oscilloscope OSC.

The vertical system VS primarily serves to offset, attenuate, and amplify a signal to be acquired. The signal can be modified, for example, to fit within the available display area of the display DISP or to have a vertical size configured by a user.

For this purpose, the vertical system VS comprises a signal conditioning section SC with an attenuator ATT and a digital-to-analog converter DAC, which are connected to an amplifier AMP. The amplifier AMP is connected to a filter FI1, which in the example shown is provided as a low-pass filter. The vertical system VS also includes an analog-to-digital converter ADC that receives the output of filter FI1 and converts the received analog signal into a digital signal.

The attenuator ATT and the amplifier AMP serve to adapt the amplitude of the signal to be acquired to the operating range of the analog-to-digital converter ADC. The digital-to-analog converter DAC serves to modify the DC component of the input signal to be acquired so that it fits within the operating range of the analog-to-digital converter ADC. Filter FI1 serves to filter out undesired high-frequency components of the signal to be acquired.

The triggering section TS operates with the signal provided by the amplifier AMP. The triggering section TS comprises a filter FI2, which in this embodiment is implemented as a low-pass filter. Filter FI2 is connected to a trigger system TS1.

The triggering section TS serves to detect predefined signal events and enables the horizontal system HS to display, for example, a stable view of a repeated waveform or simply to display waveform sections that contain the respective signal event. It is understood that the predefined signal event can be configured by a user via a user input of the oscilloscope OSC.

Possible predefined signal events can include, but are not limited to, when the signal exceeds a predefined trigger threshold in a predefined direction, i.e., with a rising or falling edge. Such a trigger condition is also referred to as an edge trigger. Another trigger condition is referred to as “glitch triggering” and triggers when a pulse occurs in the signal to be acquired whose width is greater or less than a predefined time.

To enable precise alignment of the trigger signal with the waveform displayed on the display DISP, a common time base for the analog-to-digital converter ADC and the trigger system TS1 can be provided.

It is understood that, although not explicitly shown, the trigger system TS1 can comprise at least one of the following components: configurable voltage comparators for setting the trigger thresholds, fixed voltage sources for setting the required edge, corresponding logic gates such as an XOR gate, and flip-flops for generating the trigger signal.

The triggering section TS is provided by way of example as an analog trigger section. It is understood that the oscilloscope OSC can also be equipped with a digital trigger section. Such a digital trigger section does not operate with the analog signal provided by the amplifier AMP, but with the digital signal provided by the analog-to-digital converter ADC.

A digital trigger section can comprise a processing element, such as a processor, a DSP, a CPLD, an ASIC, or an FPGA, to implement digital algorithms for detecting a valid trigger signal.

The horizontal system HS is connected to the output of the trigger system TS1 and primarily serves to position and scale the signal to be acquired horizontally on the display DISP.

The oscilloscope OSC further comprises a processing section PS that implements digital signal processing and data storage for the oscilloscope. The processing section PS comprises an acquisition processing element ACP, which is connected to the output of the analog-to-digital converter ADC, the output of the horizontal system HS, as well as to a memory MEM and a post processing element PPE.

The acquisition processing element ACP manages the acquisition of digital data from the analog-to-digital converter ADC and the storage of the data in memory MEM. The acquisition processing element ACP can comprise, for example, a processing element that has a digital interface to the analog-to-digital converter ADC and a digital interface to memory MEM. The processing element can comprise, for example, a microcontroller, a DSP, a CPLD, an ASIC, or an FPGA with corresponding interfaces. In a microcontroller or DSP, the functionality of the acquisition processing element ACP can be implemented as computer-readable instructions executed by a CPU. In a CPLD or FPGA, the functionality of the acquisition processing element ACP can be configured in the CPLD or FPGA instead of having software executed by a processor.

The processing section PS further comprises a communication processor CP and a communication interface COM.

The communication processor CP can be a device that manages data transfer to and from the oscilloscope OSC. The communication interface COM can be designed for any suitable communication standard, such as Ethernet, WIFI, Bluetooth, NFC, an infrared communication standard, and a visible light-based communication standard.

The communication processor CP is connected to memory MEM and can use memory MEM to store and retrieve data.

Naturally, the communication processor CP can also be connected to any other element of the oscilloscope OSC to retrieve device data or provide device data that is received, e.g., from a management server.

The post processing element PPE can be controlled by the acquisition processing element ACP and can access memory MEM to retrieve data to be displayed on the display DISP. The post processing element PPE can process the data stored in memory MEM so that the display DISP can display the data to a user, for example, as a waveform. The post processing element PPE can also implement analysis functions such as cursors, waveform measurements, histograms, or mathematical functions.

The display DISP controls all aspects of signal representation for a user and can, although not explicitly shown, comprise any component required to receive displayable data and control a display device to display the data as desired.

It is understood that the oscilloscope OSC, even if not shown, can comprise a user interface via which a user can interact with the oscilloscope OSC. Such a user interface can comprise dedicated input elements such as buttons and switches. At least partially, the user interface can also be provided as a touch-sensitive display device.

In the oscilloscope OSC, one of the processing elements, also called computing elements, in the processing section PS or an additional processing element can perform the function of a control unit according to the present disclosure.

It is understood that all elements of the oscilloscope OSC that perform digital data processing can be provided as dedicated elements. Alternatively, at least some of the functions described above can be implemented in a single hardware element, such as a microcontroller, DSP, CPLD, or FPGA. In general, the logical functions described above can be implemented in any suitable hardware element of the oscilloscope OSC and do not necessarily need to be divided into the various sections described above.

The processes, methods, or algorithms disclosed herein can be transferred to or implemented by a computing unit, a controller, or a computer. These can include any existing programmable electronic control unit or dedicated electronic control unit. Similarly, the processes, methods, or algorithms can be stored as data and instructions executable by a controller or computer in many forms, including but not limited to information permanently stored on non-writable storage media such as ROM devices, and information alterably stored on writable storage media such as floppy disks, magnetic tapes, CDs, RAM memory, and other magnetic and optical media. The processes, methods, or algorithms can also be implemented in a software-executable object. Alternatively, the processes, methods, or algorithms can be embedded entirely or partially in suitable hardware components such as application-specific integrated circuits (ASICs), Field-Programmable Gate Arrays (FPGAs), state machines, controllers, or other hardware components or devices, or a combination of hardware, software, and firmware components.

Although exemplary embodiments have been described above, it is understood that these embodiments do not encompass all possible forms of implementations of the present disclosure covered by the claims. The terms used in the specification are for description and not limitation, and it is understood that various changes can be made without departing from the spirit and scope of the disclosure. As previously described, the features of various embodiments can be combined to form further embodiments of the invention, which may not be explicitly described or illustrated. While various embodiments may be described as advantageous or preferred over other embodiments or implementations of the prior art with respect to one or more desired characteristics, those skilled in the art recognize that one or more characteristics or features may be altered to favor desired overall system properties depending on the specific application and implementation. These characteristics can include, but are not limited to, cost, strength, durability, lifecycle cost, marketability, appearance, packaging, size, serviceability, weight, manufacturability, ease of assembly, etc. Thus, to the extent that embodiments have been described as less desirable than other embodiments or implementations of the prior art with respect to certain characteristics, these embodiments nevertheless fall within the scope of the disclosure and may be desirable for specific applications.

Regarding the processes, systems, methods, heuristics, etc., described herein, it is understood that although the steps of such processes, etc., have been described in a specific order, such processes can also be performed in an order different from that described herein. Similarly, it is understood that certain steps can be performed concurrently, that other steps can be added, or that certain steps described herein can be omitted. In other words, the descriptions of the processes herein serve to illustrate certain embodiments and should in no way be construed as limiting the claims.

In summary, it is understood that the disclosed subject matter can be modified and varied without departing from the scope of the present disclosure.

All terms used in the claims are intended to be given their broadest reasonable constructions and their ordinary meanings as understood by those knowledgeable in the technologies described herein, unless explicitly indicated otherwise. In particular, the use of singular articles such as “a,” “the,” “said,” etc., should be read to include one or more of the specified elements, unless a claim expressly states otherwise.

### LIST OF REFERENCE SIGNS

S11, S12, S13 Method steps
S21, S22-1, S22-2, S22-3, S23 Method steps
S31, S32, S33, S34, S35 Method steps
S41, S42-1, S42-2, S43, S44 Method steps
S51, S52, S53, S54 Method steps
S61, S62, S63, S64, S65, S66 Method steps
100 Measurement system
101 Control unit
102-1, 102-2 Measurement application device
103 Control command
OSC1 Oscilloscope
HO Housing
MIP1, MIP2, MIP3, MIP4 Measurement input
SIP Signal processor
DISP1 Display
OSC Oscilloscope
VS Vertical system
SC Signal conditioning section
ATT Attenuator
DAC Digital-to-analog converter
AMP Amplifier
FI1 Filter
ADC Analog-to-digital converter
TS Triggering section
AMP2 Amplifier
FI2 Filter
TS1 Trigger system
HS Horizontal system
PS Processing section
ACP Acquisition processing element
MEM Memory
PPE Post processing element
DISP Display

1. Computer-implemented method for controlling at least one
measurement application device configured to acquire electrical signals, or generate electrical signals, or acquire and generate electrical signals, the method comprising:
acquiring at least one control command for the at least one measurement application device from a user;
automatically determining at least one further control command for the at least one measurement application device based on the at least one acquired control command; and
controlling the at least one measurement application device based on the acquired and generated control commands.

2. Method according to claim 1, wherein the automatically determining of further control commands comprises determining control commands exhibiting optimization with respect to at least one predefined goal, in particular one of the following goals:
maximizing an execution speed of a sequence of control commands;
maximizing an accuracy of the at least one measurement application device; and
optimizing a load on the at least one measurement application device.

3. Method according to claim 1 any of the preceding claims, wherein the automatically determining of further control commands comprises at least one of the following options:
determining a single control command
determining a sequence with a predefined number of control commands and
determining a sequence of control commands that completely handles a measurement task.

4. Method according to claim 1, wherein the determined further control commands comprise at least one of the following options:
control commands of a scripting language for controlling the at least one measurement application device;
configuration commands for configuring operating parameters of the at least one measurement application device;
configuration parameters for setting the operating parameters of the at least one measurement application device configuration commands for configuring a hardware of the at least one measurement application device and configuration parameters for configuring the hardware of the at least one measurement application device.

5. Method according to claim 1, further comprising:
outputting the determined at least one further control command to a user; and
receiving an approval or rejection of the determined at least one control command from the user;
wherein controlling the at least one measurement application device is executed upon receiving approval of the determined at least one control command from the user and is not executed upon rejection.

6. Method according to claim 1 any of the preceding claims, wherein the automatically determining of further control commands comprises:
transferring the at least one acquired control command to a trained AI algorithm, wherein the trained AI algorithm is trained to determine and output the further control commands based on the at least one acquired control command;

7. Method according to claim 6, wherein the automatically determining of further control commands further comprises:
transferring the at least one acquired control command to at least one further trained AI algorithm, wherein the at least one further trained AI algorithm is trained to determine and output the further control commands based on the at least one acquired control command.

8. Method according to any of claim 6, further comprising:
feeding feedback on the determined at least one further control command to the AI algorithm; and
generating further control commands based on the feedback, and/or training the AI algorithm based on the feedback.

9. Method according to any of claim 6, wherein the AI algorithm is trained based on at least one of the following options:
pre-prepared sequences of control commands for the at least one measurement application device;
descriptions of the pre-prepared sequences;
data sheets of the at least one measurement application device;
application Notes for the at least one technical device
sequences generated by the method according to claim 6; and
user feedback on the generated sequences.

10. Method according to claim 6 claims, further comprising:
storing a sequence of control commands by means of which the at least one measurement application device is controlled; and
receiving an undo input from a user, wherein the undo input relates to a control command of the sequence; and
resetting the at least one measurement application device to the state of the control command to which the undo input relates.

11. Method according to claim 6, wherein acquiring the at least one control command comprises acquiring a user input via an input interface of the at least one measurement application device; and
wherein controlling the at least one measurement application device comprises simulating a user input via the input interface of the at least one measurement application device.

12. Control unit for controlling at least one measurement application device, wherein the control unit comprises means for executing a method according to any of the preceding claims.

13. Computer program comprising instructions which, when executed by a computer, cause the computer to execute a method.

14. Computer-readable non-volatile storage medium comprising instructions which, when executed by a computer, cause the computer to execute a method.
